(19) United States
(12) Patent Application Publication
(10) Pub. No.: US 2017/0142868 A1
(43) Pub. Date: May 18, 2017

(54) HEAT-DISSIPATION SYSTEM

(71) Applicant: HON HAI PRECISION INDUSTRY CO., LTD., New Taipei (TW)

(72) Inventors: CHIN-HUI CHEN, New Taipei (TW); CHENG-HSIU YANG, New Taipei (TW); CHIA-YUN LEE, New Taipei (TW); YUEH-LIN TSAI, New Taipei (TW)

(21) Appl. No.: 14/957,007

(22) Filed: Dec. 2, 2015

(30) Foreign Application Priority Data
Nov. 13, 2015 (CN) 201510774795.6

(51) Int. Cl. H05K 7/20; F28F 23/02; F28C 1/00; F28D 15/02; F28F 23/00

(52) U.S. Cl. CPC H05K 7/20818; F28D 15/025; F28D 15/0266; F28F 23/00; F28C 1/00; F28F 23/02; H05K 7/20736; F28D 2021/0028

(57) ABSTRACT

The disclosure heat-dissipation system for a server provides a refrigeration tank configured for containing a refrigerant, a electrical component installed inside of the refrigeration tank submerged by the refrigerant and converts the refrigerant to a vapor, a cooling device installed outside of the refrigeration tank. A heat exchanger is coupled to the cooling device and installed outside of the refrigeration tank, the heat exchanger obtains the vapor from the refrigeration tank; wherein the heat exchanger exchanges the heated fluid formed by the vapor with the cooling device, for cooling the heated fluid, to return to the refrigeration tank.

### FIELD

The subject matter herein generally relates to a heat-dissipation system.

### BACKGROUND

With increasing heavy use of on-line applications, the need for computer data centers is increasing rapidly. During operation, server systems generate a lot of heat in the data centers.

### BRIEF DESCRIPTION OF THE DRAWINGS

Implementations of the present technology will now be described, by way of example only, with reference to the attached figures.

FIG. 1 is a block diagram of a first embodiment of a heat-dissipation system of the present disclosure.

FIG. 2 is a block diagram of a second embodiment of the heat-dissipation system of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

A definition that applies throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

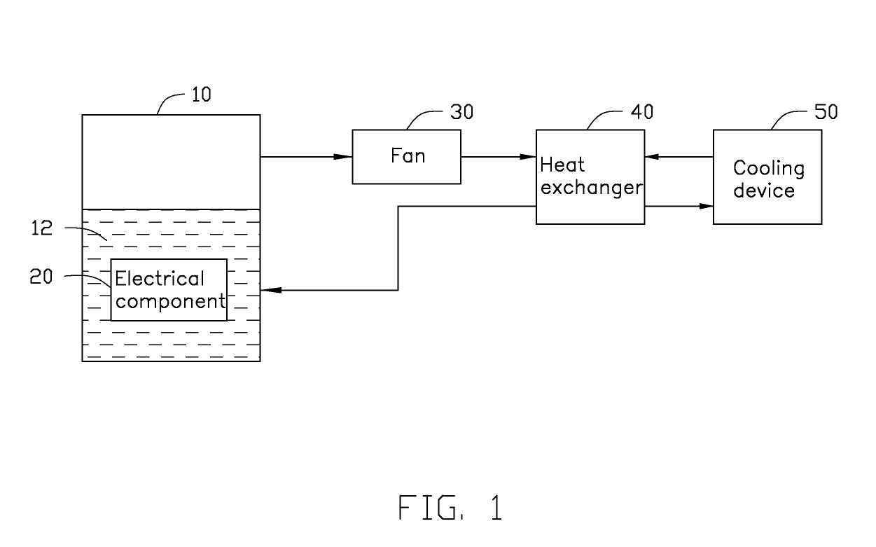

FIG. 1 illustrates a first embodiment of a heat-dissipation system of the present disclosure. The heat-dissipation system in accordance with an exemplary embodiment can comprise a refrigeration tank 10, an electrical component 20, a fan 30, a heat exchanger 40, and a cooling device 50. The refrigeration tank 10 is configured for containing a refrigerant 12. The electrical component 20 is configured for being installed inside of the refrigeration tank 10 and submerged by the refrigerant 12. In at least one embodiment, the electrical component 20 can be a motherboard of a server.

In the illustrated embodiment, both the heat exchanger 40 and the cooling device 50 are installed outside of the refrigeration tank 10. The fan 30 is coupled between the heat exchanger 40 and the refrigeration tank 10.

In the illustrated embodiment, the electrical component 20 is completely submerged in the refrigerant 12.

In the illustrated embodiment, the refrigerant 12 absorbs the heat generated by the electrical component 20, and is boiled to be a vaporized refrigerant 12. In at least one embodiment, the refrigerant 12 is an electric insulation refrigerant, and the electric insulation refrigerant is fluoride. The boiling point of the electric insulation refrigerant is between 30 centigrade and 60 centigrade, and the heat generated by the electrical component 20 can be absorbed in a timely manner by the refrigerant vapor of the refrigerant 12.

In the illustrated embodiment, the refrigerant vapor of the refrigeration tank 10 is pumped into the heat exchanger 40 through the fan 30.

In the illustrated embodiment, the heat exchanger 40 exchanges the hot fluid formed by the refrigerant vapor with the cooling device 50, for cooling the hot fluid to return to the refrigeration tank 10. In at least one embodiment, the cooling device 50 is a cooling tower.

In the illustrated embodiment, the heat exchanger 40 is installed in a position higher than the refrigeration tank 10, allowing the cold fluid refrigerant to flow back into the refrigeration tank 10.

In the illustrated embodiment, each component is connected with a seamless steel tubing to prevent the refrigerant vapor from escaping in the transmission process.

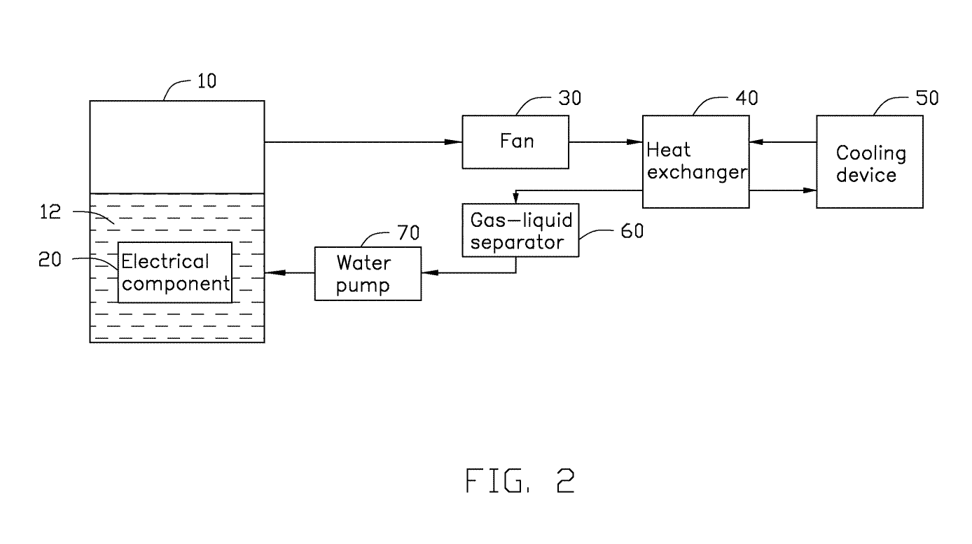

FIG. 2 illustrates a second embodiment of a heat-dissipation system. The heat-dissipation system further comprises a gas-liquid separator 60 and a water pump 70. The gas-liquid separator 60 is configured for receiving the refrigerant and refrigerant vapor from the heat exchanger 40. The water pump 70 is configured for pumping the refrigerant in cold fluid form from the gas-liquid separator 60 back to the refrigeration tank 10.

In operation, the electrical component 20 starts to heat up (such as a central processing unit of the motherboard during booting), and the fan 30 is powered by electricity. The refrigerant 12 absorbs the heat of the motherboard of the server, and part of the refrigerant 12 is boiled to be a vaporized refrigerant 12. The refrigerant vapor of the refrigeration tank 10 is pumped into the heat exchanger 40 through the fan 30. The heat exchanger 40 exchanges the hot fluid formed by the refrigerant vapor with the cooling device 50, for cooling the hot fluid, then the cooled fluid returns to the gas-liquid separator 60. In the meantime, the water pump 70 pumps the cold refrigerant fluid from the gas-liquid separator 60 back to the refrigeration tank 10, to complete the entire cycle of cooling process.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A heat-dissipation system comprising:
a refrigeration tank configured for containing a refrigerant;
an electrical component installed inside of the refrigeration tank and submerged in the refrigerant and configured for converting the refrigerant to a vapor;
a cooling device installed outside of the refrigeration tank; and
a heat exchanger coupled to the cooling device and installed outside of the refrigeration tank, the heat exchanger configured to receive the vapor from the refrigeration tank, wherein the heat exchanger exchanges the hot fluid formed by the vapor with the cooling device, thereby cooling the hot fluid to a cold fluid to return for the refrigeration tank.

2. The heat-dissipation system of claim 1, further comprising a fan coupled between the refrigeration tank and the heat exchanger, wherein the heat exchanger receives the vapor from the refrigeration tank through the fan.

3. The heat-dissipation system of claim 1, further comprising a gas-liquid separator, the gas-liquid separator is configured to receive the refrigerant and refrigerant vapor from the heat exchanger.

4. The heat-dissipation system of claim 3, further comprising a water pump, the water pump is configured to pump the refrigerant from the gas-liquid separator back to the refrigeration tank.

5. The heat-dissipation system of claim 1, wherein the electrical component is a motherboard of a server.

6. The heat-dissipation system of claim 1, wherein the cooling device is a cooling tower.

7. The heat-dissipation system of claim 1, wherein the refrigerant is an electric insulation refrigerant.

8. The heat-dissipation system of claim 7, wherein the boiling point of the electric insulation refrigerant is between 30 centigrade with 60 centigrade.

9. A heat-dissipation system comprising:
a refrigeration tank configured for containing a refrigerant;
an electrical component installed inside of the refrigeration tank and submerged in the refrigerant and configured for converting the refrigerant to a vapor;
a fan coupled to the refrigeration tank;
a cooling device installed outside of the refrigeration tank; and
a heat exchanger coupled to the cooling device and installed outside of the refrigeration tank, the heat exchanger configured to receive the vapor from the refrigeration tank through the fan, wherein the heat exchanger exchanges the hot fluid formed by the vapor with the cooling device, thereby cooling the hot fluid to a cold fluid to return to for refrigeration tank.

10. The heat-dissipation system of claim 9, further comprising a gas-liquid separator, the gas-liquid separator is configured to receive the refrigerant and refrigerant vapor from the heat exchanger.

11. The heat-dissipation system of claim 9, further comprising a water pump, the water pump is configured to pump the refrigerant from the gas-liquid separator back to the refrigeration tank.
